(19) United States
(12) Patent Application Publication
(10) Pub. No.: US 2010/0019263 A1
(43) Pub. Date: Jan. 28, 2010

(54) ROUGH STRUCTURE OF OPTOELECTRONIC DEVICE AND FABRICATION THEREOF

(75) Inventors: YING CHAO YEH, HSINCHU COUNTY (TW); SHIH CHENG HUANG, HSINCHU COUNTY (TW); PO MIN TU, HSINCHU COUNTY (TW); WEN YU LIN, HSINCHU COUNTY (TW); PENG YI WU, HSINCHU COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/505,711

(22) Filed: Jul. 20, 2009

(30) Foreign Application Priority Data
Jul. 24, 2008 (TW) 097128064

(51) Int. Cl. H01L 33/00; H01L 21/30

(52) U.S. Cl. 257/98; 438/29; 257/E33.074; 257/E21.211

(57) ABSTRACT

A dual-scale rough structure, in which a plurality of islands are grown on a semiconductor layer by heavily doping a dopant during epitaxy of a semiconductor layer of an optoelectronics device, is provided. A plurality of pin holes are formed on the islands by lowering the epitaxial temperature. The pin holes are distributed over the top and sidewall surfaces of the islands so that the total internal reflection within the optoelectronics device can be significantly reduced so as to enhance the brightness thereof. Compared with traditional technologies, the process method of the present invention has the advantages of producing less pollution, being able to perform easily, reducing manufactured cost, increasing the efficiency of light extraction, and increasing the effective area of the dual-scale emitting surface, which is not a smooth surface, of the structure.

### BACKGROUND OF THE INVENTION

1. Field of the Invention

The present invention relates to a rough structure of an optoelectronic device and the fabrication thereof, and relates more particularly to an optoelectronic device having a dual-scale rough structure and the fabrication method thereof.

2. Description of the Related Art

The light extraction efficiency of a light emitting device made of semiconductor material is determined by the internal and external quantum efficiencies thereof. Generally, the internal quantum efficiency relates to the characteristics of the material and the epitaxy quality of the device; and the external quantum efficiency relates to the reflectivity of the material and the surface flatness of the device. However, the emission efficiency of a traditional light emitting diode is limited due to the incomplete emission of the light generated therefrom, which is due to the fact that semiconductor material has, compared to air (n=1.0) or packaging materials such as epoxide (n=1.5), a higher refraction coefficient (n=2.2 to 3.8).

According to Snell's law, if the incident angle of light passing from a high refractive index medium to a low refractive index medium is larger than a critical angle, then the light undergoes total internal reflection such that it cannot enter the low refractive index medium. Most light emitted by a light emitting diode is subjected to the total internal reflection issue so as to decrease the overall emission efficiency of the light emitting diode.

One technique to minimize the total internal reflection loss is to form a structure having light scattering centers randomly distributed on the surface of a light emitting diode. The technique is disclosed by Shnitzer in a paper titled “30% External Quantum Efficiency From Surface Textured, Thin Film Light Emitting Diodes,” Applied Physics Letters 63, 2174-2176 (1993). The structure with randomly distributed centers can be formed by using polystyrene grains of sub-micron diameter as an etch mask disposed on a surface of a light emitting diode while ion beam etching is conducted. One characteristic of such a structure is that the manner of the refraction and reflection of light cannot be predicted by Snell' law at the scale of the wavelength of the emitted light. Thus, the randomization increases the overall probability of the entrance of the light into the device. As a result, the method can increase the emission efficiency of a light emitting diode from 9% to 30%.

With further reference to U.S. Pat. No. 5,779,924 issued to Krames et al., a light emitting diode having an ordered interface texture that is periodic in at least one dimension is disclosed such that the light is not directed based on randomization. The surface of the light emitting diode can couple emitted light into a specific mode or direction. The interface texture is difficult to fabricate because the shape and pattern thereof must be uniform, and the dimensions thereof are very small, approximately close to the scale of the mono-wavelength of the light emitted from the light emitting diode.

In addition, to focus light, the light output surface of a light emitting diode can be shaped to have a hemispherical configuration. U.S. Pat. No. 3,954,534 by Scifres and Burnham discloses dome shaped light emitting diodes in an array pattern, wherein each light emitting diode has a dome shaped structure. Hemispherical depressions are initially created on the top surface of a suitable substrate and a diode array is grown in the depressions. Next, the diode array and the hemispherical depressions are separated from the substrate using an etching process. The disadvantage of the method is that the method is only for creating hemispherical depressions on the top surface of a substrate, and the step of separating the hemispherical depressions from the substrate increases manufacturing cost. Moreover, each light emitting diode accompanied with a hemispherical depression requires very strict process control during manufacturing.

U.S. Pat. No. 5,040,044 discloses that roughness is formed on the surface of a light emitting diode by a chemical etch agent so as to minimize total internal reflection loss and increase light output intensity. However, the GaN group material is not easy to process because the GaN group material is highly rigid and has high resistance to effects of acidic and alkaline materials. General chemical agents and organic agents cannot etch the GaN group material. The most common method used for etching the GaN group material is the reactive ion etching process. However, such a method may have impact on the epitaxy quality and increases process complexity.

### SUMMARY OF THE INVENTION

The present invention provides a rough structure of an optoelectronic device and fabrication thereof, which can provide solutions to the limitations of traditional optoelectronic devices.

The objective of the present invention is to provide a method for fabricating a rough structure of an optoelectronic device, wherein the method initially forms a first rough layer on a semiconductor layer by heavily doping a dopant during the epitaxy of the semiconductor layer of an optoelectronic device. Next, a second rough layer is formed on the first rough layer after the epitaxial temperature is deceased. Thereafter, the first rough layer and the second rough layer are separately composed of an island array and an array of pin holes, wherein the island array comprises a plurality of randomly distributed islands and the array of pin holes comprises a plurality of randomly distributed pin holes, wherein the pin holes can be formed not only on the tops of the islands, but also on the sidewalls of the islands. As such, the optoelectronic device has a dual-scale rough structure.

To better understand the above-described objectives, characteristics and advantages of the present invention, embodiments, with reference to the drawings, are provided for detailed explanation.

### BRIEF DESCRIPTION OF THE DRAWINGS

The invention will be described according to the appended drawings in which:

FIG. 1A is a cross sectional view showing the rough structure of an optoelectronic device according to one embodiment of the present invention;

FIG. 1B is a front view showing the rough structure of the optoelectronic device of FIG. 1A;

FIG. 2 is a cross sectional view of a rough surface of an optoelectronic device according to one embodiment of the present invention;

FIG. 3A is a cross sectional view showing a rough surface of an optoelectronic device according to one embodiment of the present invention;

FIG. 3B is a front view of the rough surface of the optoelectronic device of FIG. 3A;

FIG. 4A is a flow chart of a method of fabricating a rough structure of an optoelectronic device according to one embodiment of the present invention;

FIG. 4B shows a method for fabricating a rough structure of an optoelectronic device according to one embodiment of the present invention;

FIG. 5A is a flow chart of a method for fabricating a rough structure of an optoelectronic device according to another embodiment of the present invention;

FIG. 5B shows a method for fabricating a rough structure of an optoelectronic device according to another embodiment of the present invention;

FIGS. 6A-6C is a series of photographs showing the configurations of different rough structures according to one embodiment of the present invention;

FIG. 7 is a graph showing far-field patterns measured from UV LEDs having different surface configurations according to one embodiment of the present invention; and

FIG. 8 is a graph of light intensity versus current for light emitting diodes having different surface configurations, showing measured performance of the light emitting diodes according to one embodiment of the present invention.

### DETAILED DESCRIPTION OF THE INVENTION

One aspect of the present invention proposes a rough structure of an optoelectronic device and a fabrication method thereof. In order to thoroughly understand the present invention, detailed descriptions of method steps and components are provided below. The implementations of the present invention are not limited to the specific details that are familiar to persons in the art related to a rough surface of an optoelectronic device and fabrication method thereof. On the other hand, components or method steps, which are well known, are not described in detail. A preferred embodiment of the present invention will be described in detail as follows. However, in addition to the preferred detailed description, other embodiments can be broadly employed, and the scope of the present invention is not limited by any of the embodiments, but should be defined in accordance with the following claims and their equivalent.

To increase the light extraction efficiency of an optoelectronic device, the surface of an optoelectronic device is roughened to reduce the probability of occurrence of total internal reflection so that the light generated by the optoelectronic device can be utilized more efficiently. U.S. Pat. No. 6,657,236 discloses a light emitting diode with enhanced light extraction structures having a main technical feature that an array of light extraction elements are placed in light emitting diodes and thereby change the refractive index of inner spaces in the light emitting diode. The reflection or refraction of the light emitted from the light emitting diode is based on the changed refractive index. Further, to enhance the effectiveness of the light extraction elements, the light extraction elements usually have higher refractive index than the encapsulating material of the light emitting diode so that the light refracted or reflected by the light extraction elements can transmit through the encapsulating material of the light emitting diode. The patent states that the light extraction elements are initially formed by depositing the material of the light extraction elements on a semiconductor layer of a light emitting diode by evaporation, chemical vapor deposition (CVD), or sputtering, and then a mask is formed on the material. Thereafter, reactive ion etching or a wet chemical etch is used to transfer the pattern from the mask onto the material of the light extraction elements. However, the manufacturing processes are complex and expensive, and moreover, etch processes can result in environmental pollution from the production of much waste material. Furthermore, the above-mentioned processes can only produce one scale of the light extraction elements so that the increase of the light extraction efficiency is limited.

In addition, U.S. Pat. No. 7,211,831 teaches a similar light emitting diode. The main objective of the patent is to provide a patterned surface for refracting or reflecting light, and with the help of configuration of a pattern, the light extraction performance can be improved. The above-described patterns include a periodic pattern and a non-periodic pattern, wherein the periodic pattern is a pattern that has more than one feature in each unit cell that repeats in a periodic fashion. Examples of periodic patterns include honeycomb patterns, ring patterns, and Archimidean patterns. The non-periodic patterns include quasicrystalline patterns, Robinson patterns, and Amman patterns. However, the patterned surface is formed using lithographic and etch processes, which are expensive and cause much pollution, and can only produce one scale of patterns.

Generally, when an organometallic vapor phase epitaxy (OMVPE) process is employed, the growth process of GaN group materials in a hydrogen environment is significantly different from that in a nitrogen environment. The V/III concentration ratio and concentrations of nitrogen and hydrogen in a carrier gas can be varied to control the roughness of an epitaxial surface.

Atoms on chip surfaces can have different mobility if the surfaces are formed at different epitaxial temperatures. Generally, epitaxy grown at a relatively low temperature could cause atoms on the chip surface to have low atomic mobility. Therefore, growth rate of expitaxy is usually kept intentionally low for producing good epitaxy quality and better surface flatness. In addition, the control of the growth temperature and rate can also roughen the chip surface.

Furthermore, when the OMVPE method is applied to grow GaN group materials, and ammonia gas is used as the source of nitrogen atoms, the growth temperature of epitaxial layers, excluding the light emitting active layer which must be grown at low temperature due to the existence of indium element, should be in the range of from about 1000° C. to 1200° C. if considering grown material rigidity and the dissociation rate of the ammonia gas.

In accordance with the above discussion, U.S. Pat. No. 6,441,403 discloses a method for roughening a surface of a light emitting device. The method relies on epitaxial growth techniques to roughen a surface of a light emitting device. For example, changing environmental conditions such as V/III concentration ratio, constituent concentrations of a gas carrier, temperature, pressure and growth rate allows an operator to grow an epitaxial layer with a roughened surface. Specifically, the method discloses a p-type or n-type GaN layer, which is grown at a temperature lower than 1000° C. and can be used as an electrode contact layer. Namely, a roughened surface is formed due to the low atomic mobility on the chip surface. The method teaches that a sapphire substrate ready for growing expitaxy is initially loaded into an organometallic vapor phase epitaxy growth reactor. The sapphire substrate is then preheated for 10 minutes at a temperature of 1150° C. Next, the temperature of the sapphire substrate is lowered to a temperature between about 500° C. and 600° C. When the temperature of the sapphire substrate reaches 520° C., a GaN buffer layer with a thickness of 25 nm is grown on the surface of the substrate. Next, the sapphire substrate is heated up to 1100° C. and a Si-doped (n-type silicon doped) GaN layer with a thickness of about 4 μm is grown at a rate of about 2 μm/hr on the buffer layer. Next, the sapphire substrate is cooled down to about 820° C. and an InGaN/GaN multiple quantum well structure or a double-hetero structure is grown on the surface of the n-type Si-doped GaN layer. Next, the temperature is increased to 1100° C. and a p-type Mg-doped GaN smooth layer is grown on the surface of the InGaN/GaN multiple quantum well structure. Finally, a roughened p-type Mg-doped GaN layer is intentionally formed at a relatively low temperature by changing growth parameters. Although the method simplifies process steps and reduces pollution and cost, the method can only generate a roughened surface of a single scale.

Similarly, WO 2007/058474 provides a method for producing a dual-scale rough surface. The method initially teaches the formation of a rough surface having a plurality of hexagonal pinholes on a semiconductor layer by lowering the temperature for epitaxially growing the semiconductor layer. Next, a masking film is formed on the rough surface. A plurality of protrusions are formed on the planar portions, having no pinholes, of the rough surface so that dual-scale rough surface can be produced. Although such a dual-scale rough surface can overcome the drawback of the roughened surface of a single scale, the protrusions are merely distributed on the planar portion having no pinholes, and the inclined surfaces of the pinholes are still smooth. Therefore, the method cannot roughen the entire surface of the semiconductor layer. Moreover, to create the dual-scale rough surface requires an etching process, combined with a masking film, to form the protrusions, and therefore, the method still has issues such as high pollution and high cost.

In view of the above issues, the present invention proposes a method for fabricating an optoelectronic device having a rough structure. The method heavily dopes a dopant to form a first roughened layer during an epitaxial process for a semiconductor layer of an optoelectronic device at an environmental temperature ranging from about 1000° C. to about 2000° C. Next, the epitaxial temperature is lowered to a temperature in the range of from 200° C. to 650° C. and a second roughened layer is formed on the first roughened layer. The above-mentioned dopant comprises magnesium, silicon or a combination of magnesium and silicon, and the concentration of the dopant is between about 1×10²⁰ and about 9.9×10²² cm⁻³.

When the heavily doped semiconductor layer is formed using an epitaxy process, a plurality of islands, randomly distributed, are formed on the semiconductor layer so as to roughen the semiconductor layer as a first rough layer. When the first rough layer continues to grow at a lower epitaxial temperature, an array of pin holes are randomly formed on the first rough layer and finally become a second rough layer. The pin holes are formed not only on the top of the islands, but on the sidewalls of the islands as well such that the entire semiconductor layer can be completely roughened. As a result, a perfect dual-scale rough structure can be produced. The rough structure can be formed in the interior or surfaces of an optoelectronic device for reflecting or refracting emitted light so as to improve the light extraction efficiency.

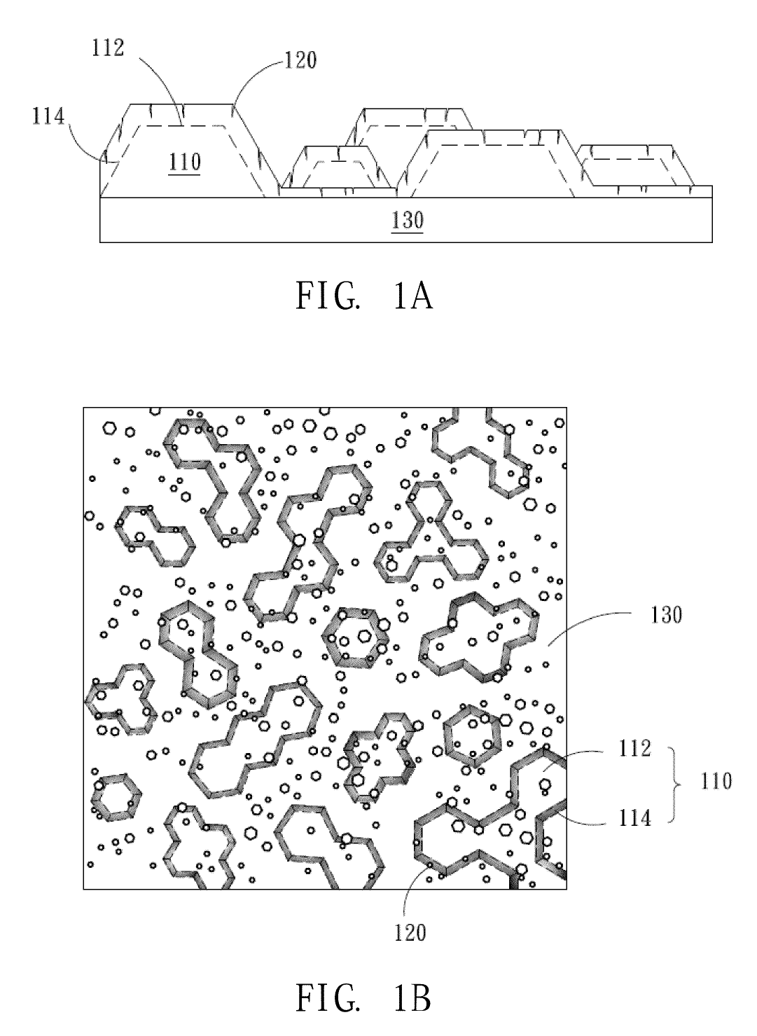

To grow the above-mentioned pin holes, U.S. Pat. No. 7,385,226 has disclosed relative technical information. The patent provides a light emitting device, which comprises a substrate; a first nitride semiconductor stacking layer formed on the substrate; a nitride light-emitting layer formed on the first nitride semiconductor stack in parallel to a surface of the substrate; a second nitride semiconductor stacking layer formed on the nitride light-emitting layer, wherein a plurality of hexagonal-pyramid cavities extend downward from a surface of the second nitride semiconductor stack and opposite to the nitride light-emitting layer. The hexagonal-pyramid cavities grow at an epitaxial temperature between 700° C. and 950° C. for facilitating crystal nucleation so as to form the hexagonal-pyramid cavities on the surface of the p-type nitride semiconductor stacking layer or within the p-type nitride semiconductor stacking layer. Changing the epitaxial temperature and the epitaxial temperature ascending and descending rates can control the scales and densities of the hexagonal-pyramid cavities and affect the light extraction efficiency. Referring to FIGS. 1A and 1B, which are respectively a cross sectional view and a front view of the rough structure of an optoelectronic device fabricated according to the above-mentioned method, the rough structure comprises a plurality of islands 110 and a plurality of pin holes 120, wherein the plurality of islands 110 are distributed over a semiconductor layer 130 of an optoelectronic device, and the plurality of pin holes 120 are distributed on the tops 112 and sidewalls 114 of the plurality of islands 110. Moreover, the plurality of pin holes 120 can be distributed on the semiconductor layer 130 and between the plurality of islands 110. That is, the plurality of pin holes 120 can be formed either on the tops 112 and sidewalls 114 of said plurality of islands 110, or on the semiconductor layer 130 and between the plurality of islands 110. As a result, dual-scale roughness can be obtained. The material of both the plurality of islands 110 and the semiconductor layer 130 can be p-type gallium nitride (P—GaN), n-type gallium nitride (N—GaN), p-type aluminum gallium nitride (P—AlGaN), or n-type aluminum gallium nitride (N—AlGaN). The scale ratio of the island 110 to the pin hole 120 is in the range of from about 1000:1 to about 10:1, wherein the scale of the island 110 ranges from about 0.1 to about 10 μm, and the scale of the pin hole 120 is greater than or equal to one-eighth of the wavelength of the light from the optoelectronic device. The diameter of the pin hole 120 is in the range of from about 10 to about 1000 nm, and the density of the plurality of pin holes 120 is in the range of from about 10⁷ to about 10¹¹ cm².

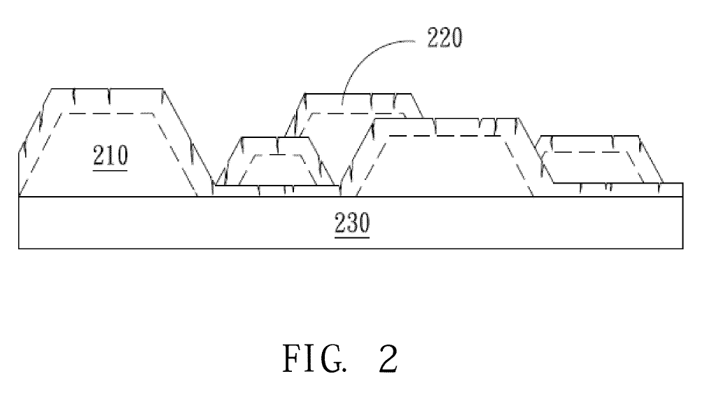

FIG. 2 is a cross sectional view of a rough surface of an optoelectronic device according to one embodiment of the present invention. Referring to FIG. 2, the rough surface comprises a first rough surface 210 formed on the surface 230 of an optoelectronic device and a second rough surface 220 formed on the first rough surface 210. Similarly, the first rough surface 210, the second rough surface 220 and the surface 230 of the optoelectronic device can be on a p-type gallium nitride layer or n-type gallium layer. The roughness ratio of the first rough surface 210 to the second rough surface 220 is in the range of from about 1000:1 to about 10:1, wherein the scale of the first rough surface 210 ranges from about 0.1 and about 10 μm, and the scale of the second rough surface 220 is greater than or equal to one-eighth of the wavelength of the light from the optoelectronic device.

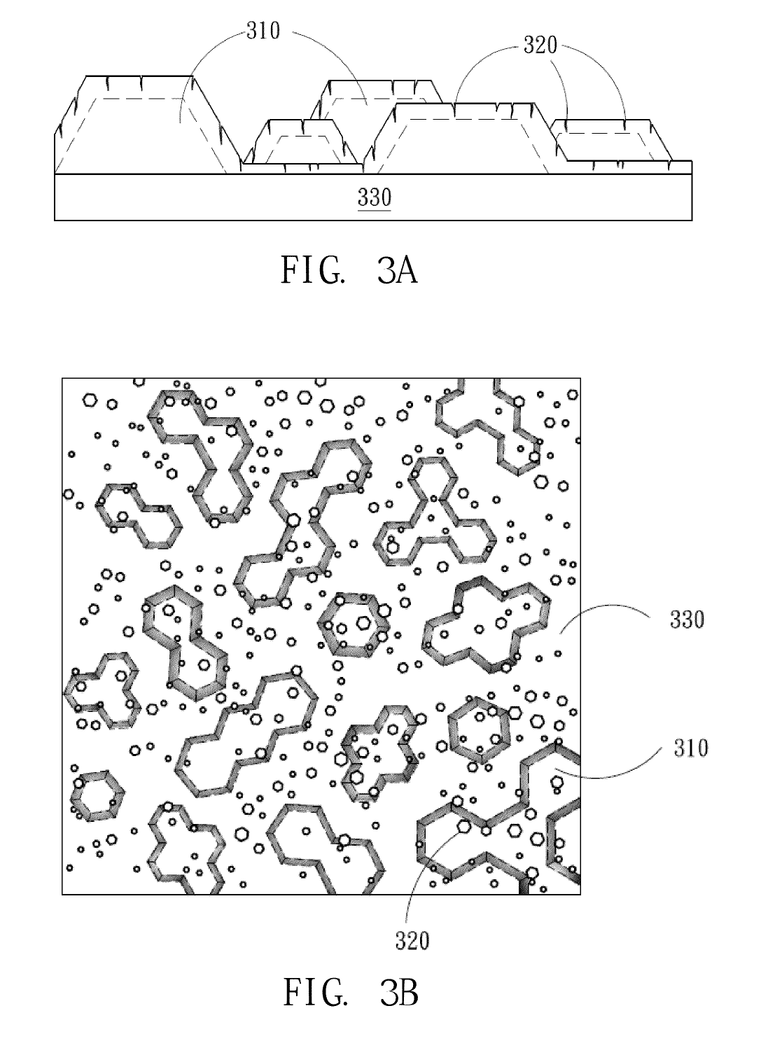

FIG. 3A is a cross sectional view showing a rough surface of an optoelectronic device according to one embodiment of the present invention and FIG. 3B is a front view of the rough surface of optoelectronic device of FIG. 3A. The rough structure comprises an island array 310 and an array of pin holes 320, wherein the elements of the island array 310 are randomly distributed over a surface 330 of an optoelectronic device, and the array of pin holes 320 are also randomly distributed on the plurality of islands 320, wherein the plurality of pin holes 320 are randomly distributed on the tops and sidewalls of the islands of the island array 310. The island array 310, the array of pin holes 320 and the surface 330 can be on a layer of p-type gallium nitride or n-type gallium nitride. The scale ratio of the islands of the island array 310 to the pin holes of the array of pin holes 320 is in the range of from about 1000:1 to about 10:1, wherein the scale of the islands of the island array 310 ranges from about 0.1 and about 10 μm, and the scale of the diameter of the pin hole of the pin hole array 320 is greater than or equal to one-eighth of the wavelength of the light from the optoelectronic device, or is in the range of from about 10 to about 1000 nm.

In other words, the plurality of islands 110, a first rough surface 210 and the island array 310 are eptaxially formed with heavy doping of a dopant on a semiconductor layer or a surface to obtain a doped layer (“first rough layer”). Further, the plurality of pin holes 120, the second rough surface 220 and the array of pin holes 320 can be obtained by continuously epitaxially growing a low temperature layer (“second rough layer”) on the doped layer after lowering the epitaxial temperature used to form the doped layer.

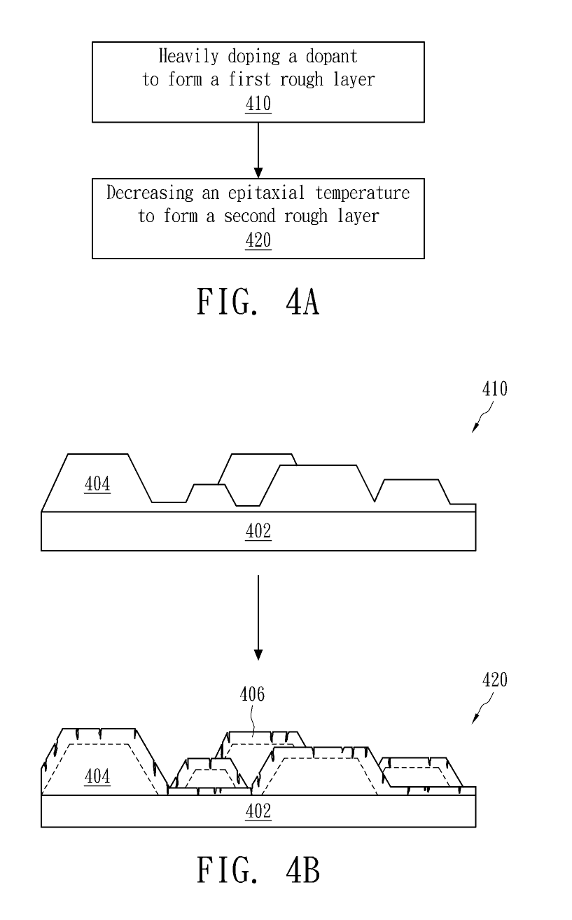

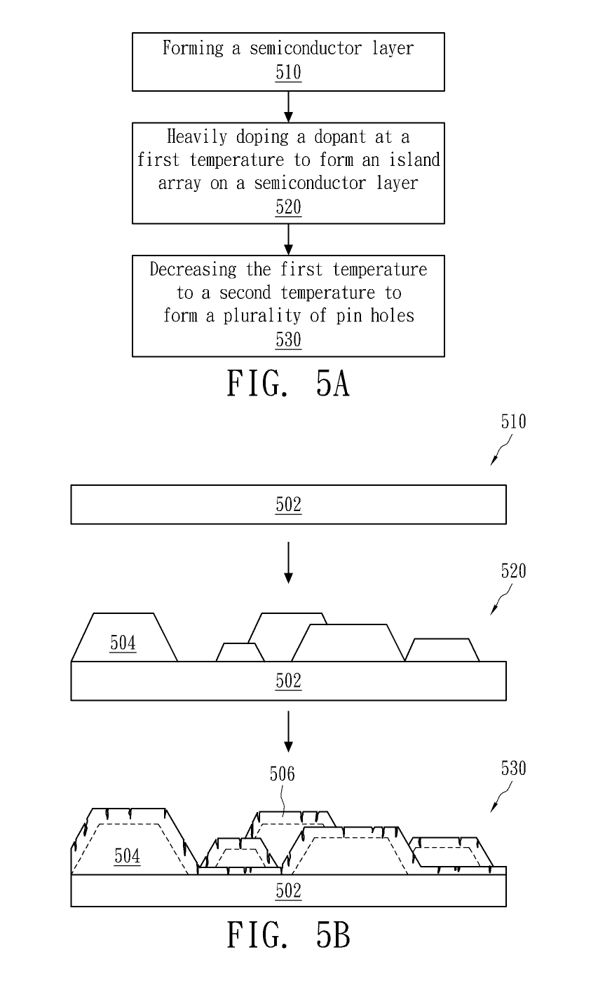

Referring to FIGS. 4A and 4B, the present invention proposes a method for fabricating a rough structure of an optoelectronic device. In Step 510, a semiconductor layer 502 is formed. In Step 520, at a first temperature, the semiconductor layer 502 is heavily doped with a dopant to form a plurality of islands 504 on the semiconductor layer 502. In Step 530, the first temperature is decreased to a second temperature to form a plurality of pin holes 506, wherein the plurality of pin holes 506 are formed on the tops and sidewalls of the plurality of islands 504, and can moreover be formed on the semiconductor layer 502 and between the plurality of islands 504. More specifically, the first temperature is higher than the second temperature, wherein the first temperature is in the range of from 1000° C. to 1200° C., and the second temperature is in the range of from 500° C. to 950° C.

Analogously, the present invention provides a method for fabricating a rough structure of an optoelectronic device. Initially, a semiconductor layer is epitaxially formed in processes for an optoelectronic device. Next, an island array is formed from the semiconductor layer by heavily doping of a dopant. Finally, the epitaxial temperature is lowered to form an array of pin holes each having a diameter larger than or equal to one-eighth of the wavelength of the light from the optoelectronic device, wherein the pin holes are randomly distributed on the tops and sidewalls of the islands of the island array. Similarly, the present invention further provides a method for fabricating a rough structure of an optoelectronic device. Initially, a first rough surface is formed from a surface of an optoelectronic device by heavily doping a dopant. Next, a second rough surface, the roughness of which is larger than or equal to one-eighth of the wavelength of the light from the optoelectronic device, is formed on the first rough surface by lowering the process temperature.

The dopant can be magnesium, silicon, or a combination of magnesium and silicon, and in the embodiments of the present invention, the concentration of the dopant, preferably, is in the range of from about 1×10²⁰ to about 9.9×10²² cm⁻³. In addition, the epitaxial temperature for the semiconductor layer, the first rough layer, the plurality of islands, the island array, and the first rough surface can approximately be in the range of from 1000° C. to 1200° C., and the epitaxial temperature for the second rough layer, the plurality of pin holes, the array of pin holes or the second rough surface can approximately be in the range of from 500° C. to 950° C., wherein the temperature difference between the two epitaxial temperatures is roughly in the range of from 200° C. to 650° C. Furthermore, the material of the semiconductor layer of the optoelectronic device can be p-type gallium nitride or n-type gallium nitride, and the first rough layer and the second rough layer, or the plurality of islands or the island array and the array of pin holes, or the first rough surface and the second rough surface can be made of the same material as the semiconductor layer.

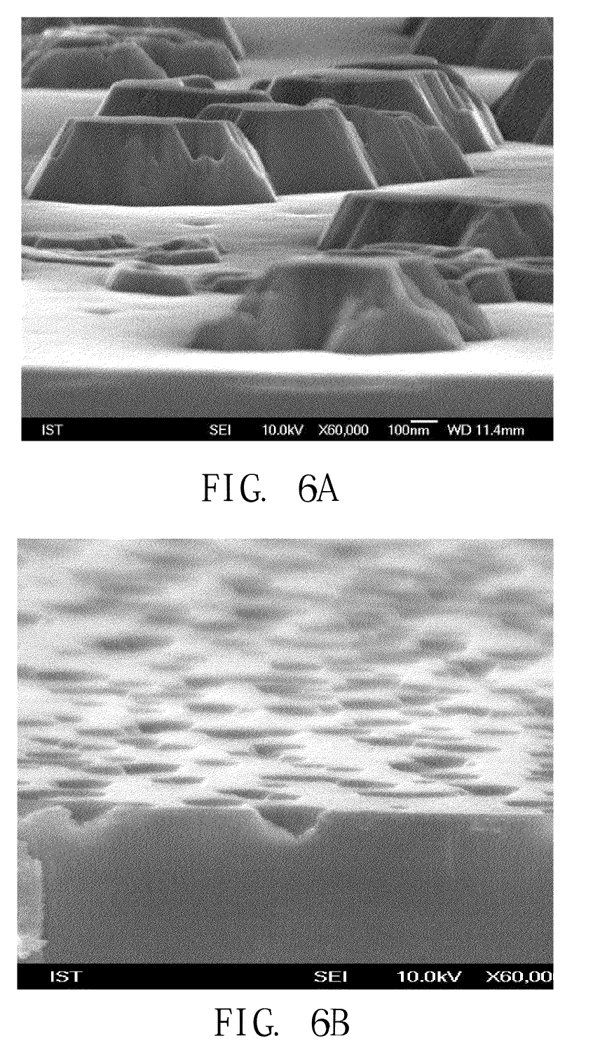

Referring to FIGS. 6A to 6C, FIG. 6A shows the configurations of the islands formed on a semiconductor layer while magnesium is doped with high concentration ranging from about 1×10²⁰ to about 9.9×10²² cm⁻³. FIG. 6B shows the configuration of the pin holes formed at a relatively low epitaxial temperature between about 500° C. and about 950° C. FIG. 6C shows a dual-scale rough structure formed by the above-described process conditions.

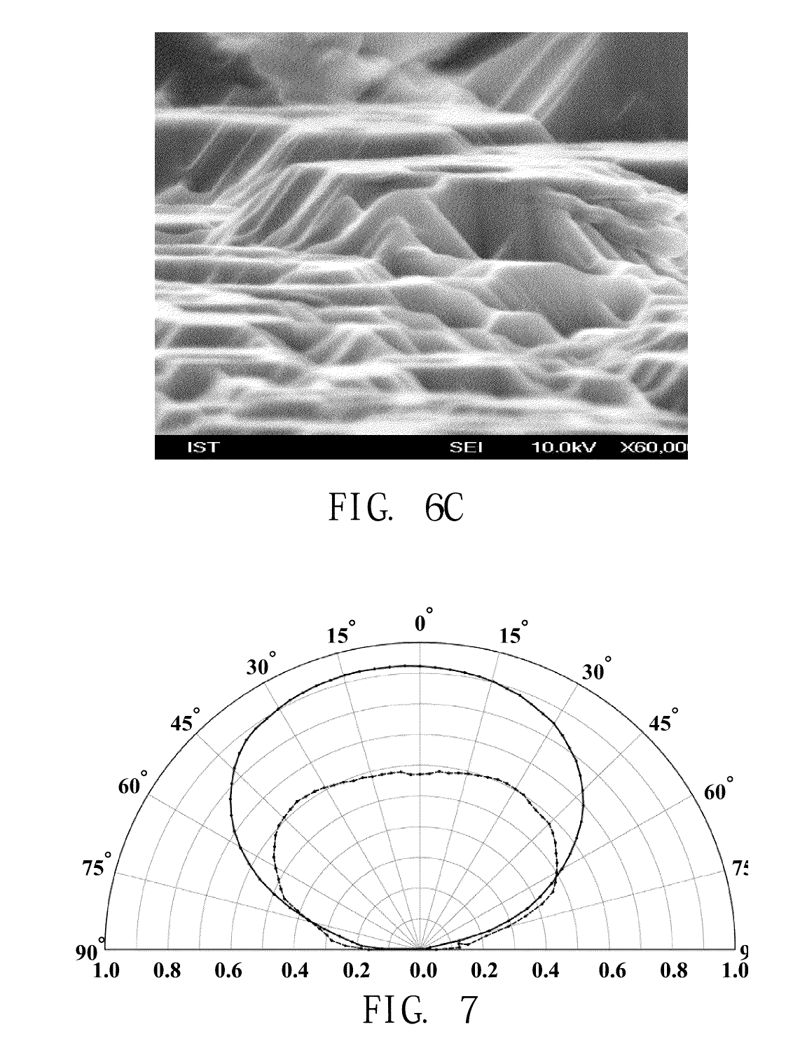

FIG. 7 shows far-field patterns measured from UV LEDs having different surface configurations, wherein the solid line represents the performance of a light emitting diode having a dual-scale rough structure, and the dashed line represents the performance of a light emitting diode having a smooth surface. It can be seen that the light emitting diode having a dual-scale rough structure performs much better than the light emitting diode having a smooth surface.

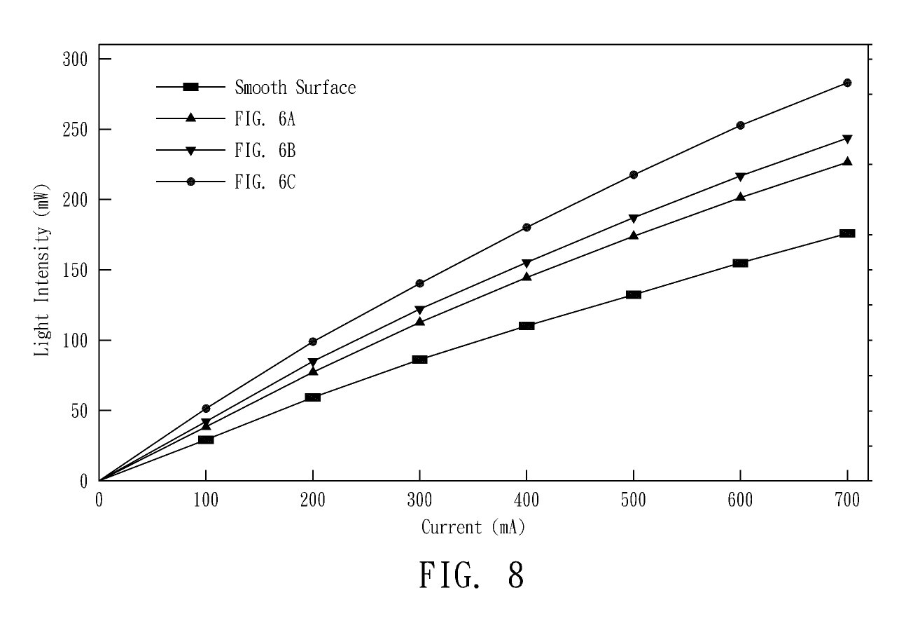

FIG. 8 is a graph of light intensity versus current for light emitting diodes having different surface configurations, showing measured performance of the light emitting diodes according to one embodiment of the present invention. The curve with rectangular dots represents a light emitting diode having a smooth surface; the curve with upright triangular dots represents the light emitting diode having the rough surface, on which only islands in FIG. 6A are formed; the curve with inverse triangular dots represents the light emitting diode having the rough surface, on which only pin holes in FIG. 6B are formed; the curve with circular dots represents the light emitting diode having the rough surface, on which dual-scale structures in FIG. 6C are formed. According to FIG. 8, the light emitting diode with dual-scale structure has better light emission efficiency than the light emitting diode having a one-scale rough surface or the light emitting diode having a smooth surface.

The above-described embodiments of the present invention are intended to be illustrative only. Numerous alternative embodiments may be devised by persons skilled in the art without departing from the scope of the following claims.

What is claimed is:

1. A rough structure of an optoelectronic device, comprising:
a plurality of islands distributed over a semiconductor layer of an optoelectronic device; and
a plurality of pin holes distributed on the tops and sidewalls of said plurality of islands.

2. The rough structure of an optoelectronic device according to claim 1, wherein the scale of said island is in the range of from about 0.1 to about 10 μm.

3. The rough structure of an optoelectronic device according to claim 2, wherein the diameter of said pin hole is in the range of from about 10 to about 1000 nm, and the density of said plurality of pin holes is in the range of from about 10⁷ to about 10¹¹ cm⁻².

4. The rough structure of an optoelectronic device according to claim 3, wherein the scale of said pin hole is greater than or equal to one-eighth of the wavelength of the light from said optoelectronic device.

5. The rough structure of an optoelectronic device according to claim 2, wherein the scale ratio of said island to said pin hole is in the range of from about 1000:1 to about 10:1.

6. The rough structure of an optoelectronic device according to claim 1, wherein said plurality of pin holes are distributed on said semiconductor layer and between said plurality of islands.

7. The rough structure of an optoelectronic device according to claim 6, wherein said optoelectronic device is a light emitting diode.

8. A rough surface of an optoelectronic device, comprising:
a first rough surface formed on the surface of said optoelectronic device; and
a second rough surface formed on said first rough surface, wherein the scale of said second rough surface is greater than or equal to one eighth of the wavelength of the light from said optoelectronic device.

9. The rough surface of an optoelectronic device according to claim 8, wherein the scale ratio of said first rough surface to said second rough surface is in the range of from about 1000:1 to about 10:1.

10. The rough surface of an optoelectronic device according to claim 9, wherein the rough scale of said first rough surface is in the range of from about 0.1 to about 10 μm and the rough scale of said second rough surface is in the range of from about 10 to about 1000 nm.

11. The rough surface of an optoelectronic device according to claim 10, wherein said optoelectronic device is a light emitting diode.

12. The rough surface of an optoelectronic device according to claim 8, wherein said surface of said optoelectronic device, said first rough surface and said second rough surface are formed on P—GaN, N—GaN, P—AlGaN, or N—AlGaN layers.

13. A method for fabricating a rough structure of an optoelectronic device, comprising steps of:
forming a semiconductor layer;
heavily doping a dopant to form an island array on said semiconductor layer; and
decreasing an epitaxial temperature to form an array of pin holes, wherein the diameter of each pin hole is greater than or equal to one-eighth of the wavelength of the light from said optoelectronic device, and said array of pin holes is distributed randomly on the top and sidewall of said island array.

14. The method for fabricating a rough structure of an optoelectronic device according to claim 13, wherein the concentration of said dopant is in the range of from about 1×10²⁰ to about 9.9×10²² cm⁻³.

15. The method for fabricating a rough structure of an optoelectronic device according to claim 14, wherein the temperature decrease at said step of decreasing an epitaxial temperature is in the range of from about 200° C. to about 650° C.

16. The method for fabricating a rough structure of an optoelectronic device according to claim 13, wherein said semiconductor layer, said island array, and said array of pin holes are made of P—GaN, N—GaN, P—AlGaN, or N—AlGaN.

17. The method for fabricating a rough structure of an optoelectronic device according to claim 15, wherein the fabricating temperature of said array of pin holes is in the range of from about 500° C. to about 950° C.

18. The method for fabricating a rough structure of an optoelectronic device according to claim 17, wherein the scale ratio of said island array to said array of pin holes is in the range of from about 1000:1 to about 10:1.

19. The method for fabricating a rough structure of an optoelectronic device according to claim 18, wherein the scale of said island array is in the range of from about 0.1 to about 10 μm; the diameter of said pin hole is in the range of from about 10 to about 1000 nm, and the density of said pin holes is in the range of from about 10⁷ to about 10¹¹ cm⁻².

20. The method for fabricating a rough structure of an optoelectronic device according to claim 18, wherein said dopant includes Mg, Si, or a combination thereof.
